(19) United States
(12) Patent Application Publication
(10) Pub. No.: US 2026/0304829 A1
(43) Pub. Date: Oct. 1, 2026

(54) POWER DEVICE AND MANUFACTURING METHOD THEREOF

(71) Applicant: CHONGQING SIMIC SEMICONDUCTOR LIMITED, CHONGQING (CN)

(72) Inventor: LI YANG, CHONGQING (CN)

(21) Appl. No.: 19/632,410

(22) Filed: Mar. 30, 2026

(30) Foreign Application Priority Data
Mar. 31, 2025 (CN) 202510396947.7

(51) Int. Cl. H10D 30/66; H10D 30/01; H10D 62/10

(52) U.S. Cl. CPC H10D 30/665; H10D 30/0297; H10D 30/668; H10D 62/107

(57) ABSTRACT

A power device and a manufacturing method thereof are provided. The power device comprises a substrate, an epitaxial layer disposed on the substrate, and an isolation layer disposed on the epitaxial layer. The power device is divided into a gate contact region, an active region, a termination region, and a termination peripheral region along a horizontal direction. A gate metal is disposed on a portion of the isolation layer within the gate contact region. A source metal is disposed on the isolation layer within the active region. Voltage-withstanding rings and at least one field ring are disposed in the termination region. A drain metal is disposed on a portion of the isolation layer within the termination peripheral region. The drain metal is connected to a portion of a first implantation region within the termination peripheral region. The drain metal is disposed on a front side of the power device.

### TECHNICAL FIELD

The present disclosure relates to a field of semiconductor power devices, and in particular to a power device and a manufacturing method thereof.

### BACKGROUND

In a field of high-frequency applications, it is necessary to integrate high-side and low-side power transistors with a control Integrated Circuit (IC) into a DrMOS (Driver and MOSFET, which is a power module integrating a driver and a metal-oxide-semiconductor field-effect transistor, and is generally implemented through System-in-Package). Since a source metal and a drain metal of a MOSFET device in the prior art are generally distributed vertically (i.e., a source metal thereof is on a front side of the MOSFET device and a drain metal is on a rear side of the MOSFET device), clip (copper clip) frames are required to connect the high-side power transistor and the low-side power transistor. From a perspective of product-level cost control, there is a need to reduce consumption of clip materials, which requires the source metal, the drain metal, and a gate metal to be fabricated on a single plane of the MOSFET device. In the prior art, packaging processes such as flip-chip are generally adopted to meet a requirement of having a rear-side drain of a certain MOSFET facing upward within a co-packaged device. However, the requirement of having the drain metal, the source metal, and the gate metal of the MOSFET device on the single plane is unable to be realized.

### SUMMARY

In view of shortcomings of the prior art, a technical problem to be solved by the present disclosure is to provide a power device with a drain disposed on a front side thereof and a manufacturing method thereof.

In a first aspect, the present disclosure provides a power device. The power device comprises a substrate, an epitaxial layer disposed on the substrate, and an isolation layer disposed on the epitaxial layer. The power device is divided into a gate contact region, an active region, a termination region, and a termination peripheral region along a horizontal direction. A first implantation region is disposed above the epitaxial layer. A portion of the first implantation region within the gate contact region and the active region forms a body region. Gate interconnection structures are disposed in a portion of the epitaxial layer within the gate contact region. A gate metal is disposed on a portion of the isolation layer within the gate contact region. The gate metal is connected to the gate interconnection structures.

Trench gates and second implantation regions are disposed in a portion of the epitaxial layer within the active region. Each of the second implantation regions is disposed on one side of a corresponding one of the trench gates to form a source region. A source metal is disposed on the isolation layer within the active region, and the source metal is connected to each source region. Voltage-withstanding rings and a field ring structure are disposed in the termination region. A drain metal is disposed on a portion of the isolation layer within the termination peripheral region. The drain metal is connected to a portion of the first implantation region within the termination peripheral region.

In a second aspect, the present disclosure provides a manufacturing method for a power device. The manufacturing method comprises steps S100-S600.

The S100 comprises growing an epitaxial layer on a substrate.

The S200 comprises dividing a gate contact region, an active region, a termination region, and a termination peripheral region along a horizontal direction, forming gate interconnection structures in the gate contact region, forming trench gates in the active region, and forming voltage-withstanding rings and at least one field ring in the termination region.

The step S300 comprises forming a first implantation region in an upper portion of the epitaxial layer by ion implantation. A thickness of the first implantation region is less than a depth of the at least one field ring. A portion of the first implantation region within the gate contact region and the active region form a body region.

The step S400 comprises forming a source region on one side of each of the trench gates by ion implantation.

The step S500 comprises depositing an isolation layer on the epitaxial layer, and manufacturing gate interconnection contacts, source contacts, field ring contacts, and drain contacts that extend through the isolation layer. The gate interconnection contacts are respectively connected to the gate interconnection structures. Each of the source contacts is connected to a corresponding source region. One of the field ring contacts is connected to the at least one field ring. The drain contacts are connected to a portion of the first implantation region within the termination peripheral region.

The step S600 comprises performing metallization deposition on the isolation layer, and forming a gate metal, a source metal, a field ring metal, and a drain metal that are isolated from each other by photolithography and etching. The gate metal is connected to the gate interconnection contacts, the source metal is connected to the source contacts, the field ring metal is connected to the field ring contacts, and the drain metal is connected to the drain contacts.

In the present disclosure, from a perspective of product-level cost control and through simulation experiments on the power device, it is found that a potential on a front side of the power device within the termination peripheral region is substantially the same as a potential of the substrate on a rear side of the power device. Accordingly, the drain metal on the rear side of the power device is instead disposed within the termination peripheral region on the front side of the power device, so that the source metal, the drain metal, and the gate metal of the power device are all located on a single plane, which effectively reduces a requirement for clip materials, enhances performance of the power device, and reduces parasitic effects.

### BRIEF DESCRIPTION OF DRAWINGS

FIG. 1 is a schematic diagram of a power device according to one embodiment of the present disclosure.

FIG. 2 is a potential simulation diagram of a P_UMOS product and an N_UMOS product according to one embodiment of the present disclosure.

FIG. 3 is a flowchart of a manufacturing method of the power device according to one embodiment of the present disclosure.

FIG. 4 is a schematic diagram of a structure obtained after growing an epitaxial layer on a substrate.

FIG. 5 is a schematic diagram of a structure obtained after etching trenches.

FIG. 6 is a schematic diagram of a structure obtained after forming a first implantation region.

FIG. 7 is a schematic diagram of a structure obtained after forming source regions.

FIG. 8 is a schematic diagram of a structure obtained after forming an isolation layer.

FIG. 9 is a schematic diagram of a structure obtained after forming contact holes.

FIG. 10 is a schematic diagram of a structure obtained after forming a source metal, a drain metal, a field ring metal, and a gate metal.

### DETAILED DESCRIPTION

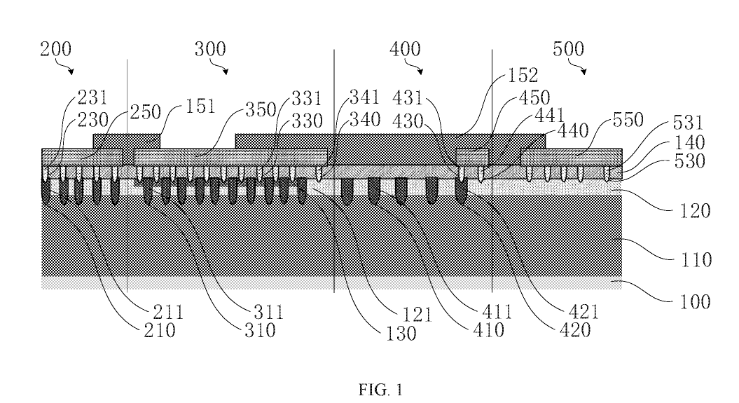

FIG. 1 is a schematic diagram of a power device with a front-side drain according to one embodiment of the present disclosure.

The power device in the embodiment comprises a substrate 100, an epitaxial layer 110 disposed on the substrate 100, and an isolation layer 140 disposed on the epitaxial layer 110. A lower end of the substrate 100 is a rear side of the power device, and one side of the power device opposite to the rear side is defined as a front side of the power device. The power device is divided into a gate contact region 200, an active region 300, a termination region 400, and a termination peripheral region 500 along a horizontal direction. A first implantation region 120 is disposed in an upper portion of the epitaxial layer 110, and a portion of the first implantation region 120 within the gate contact region 200 and the active region 300 forms a body region 121.

Gate interconnection structures 211 are disposed in a portion of the epitaxial layer 110 within the gate contact region 200, a gate metal 250 is disposed on a portion of the isolation layer 140 within the gate contact region 200, and the gate metal 250 is connected to the gate interconnection structures 211. In the embodiment, gate interconnection trenches 210 are formed in the gate contact region 200, a depth of each of the gate interconnection trenches 210 is greater than a depth of the body region 121, and the gate interconnection structures 211 are formed by respectively depositing polysilicon in the gate interconnection trenches 210. Gate interconnection contact holes 230 extending through the isolation layer 140 and into the gate interconnection structures 211 are formed on the portion of the isolation layer 140 within the gate contact region 200. Gate interconnection contacts 231 are respectively formed in the gate interconnection contact holes 230. The gate metal 250 is connected to the gate interconnection structures 211 through the gate interconnection contacts 231.

Trench gates 311 are disposed in a portion of the epitaxial layer 110 within the active region 300. A second implantation region is disposed on one side of each of the trench gates 311 to form a source region 130. A source metal 350 is disposed on a portion of the isolation layer 140 within the active region 300. The source metal 350 is connected to each source region 130. In the embodiment, gate trenches 310 are formed in the active region 300. A depth of each of the gate trenches 310 is greater than the depth of the body region 121. The trench gates 311 are formed by respectively depositing the polysilicon in the gate trenches 310. First active region contact holes 330 and a second active region contact hole 340 are formed on the portion of the isolation layer 140 within the active region 300. The first active region contact holes 330 extend through the isolation layer 140 and into the source region 130. The second active region contact hole 340 extends through the isolation layer 140 and into a portion of the body region 121 between the trench gates 311 and voltage-withstanding rings 411. First source contacts 331 are respectively formed in the first active region contact holes 330. A second source contact 341 is formed in the second active region contact hole 340. Each source region 130 is connected to the source metal 350 through a corresponding one of the first source contacts 331. The source metal 350 is connected to the portion of the body region 121 between the gate trenches 310 and voltage-withstanding ring trenches 410 through the second source contact 341.

Voltage-withstanding rings 411 and a field ring structure are disposed within the termination region 400. In the embodiment, the voltage-withstanding ring trenches 410 and at least one field ring trench 420 are formed in the termination region 400, and the at least one field ring trench 420 is located on one side of the termination region 400 away from the active region 300. Depths of the voltage-withstanding ring trenches 410 and the at least one field ring trench 420 are all greater than the depth of the body region 121. The voltage-withstanding rings 411 are formed by respectively depositing the polysilicon in the voltage-withstanding ring trenches 410. The at least one field ring 421 is formed by depositing the polysilicon in the at least one field ring trench 420. A first field ring contact hole 430 and a second field ring contact hole 440 are formed on a portion of the isolation layer 140 within the termination region 400. The first field ring contact hole 430 extends through the isolation layer 140 and into the at least one field ring 421. The second field ring contact hole 440 extends through the isolation layer 140 and into a portion of the first implantation region 120 on one side of the at least one field ring 421 adjacent to the termination peripheral region 500. A first field ring contact 431 is formed in the first field ring contact hole 430, and a second field ring contact 441 is formed in the second field ring contact hole 440. A field ring metal 450 is formed on the portion of the isolation layer 140 within the termination region 400. The field ring metal 450 covers an upper end of the first field ring contact hole 430 and an upper end of the second field ring contact hole 440. The field ring metal 450 is connected to the at least one field ring 421 through the first field ring contact 431, and the field ring metal 450 is connected to the first implantation region 120 through the second field ring contact 441, so as to form the field ring structure.

A drain metal 550 is disposed on a portion of the isolation layer 140 within the termination peripheral region 500. The drain metal 550 is connected to a portion of the first implantation region 120 within the termination peripheral region 500. In the embodiment, drain pad contact holes 530 extending through the isolation layer 140 and into the first implantation region 120 are formed on the portion of the isolation layer 140 within the termination peripheral region 500. Drain contacts 531 are respectively formed in the drain pad contact holes 530. The drain metal 550 is connected to the portion of the first implantation region 120 within the termination peripheral region 500 through the drain contacts 531.

A first isolation passivation layer 151 is formed between the gate metal 250 and the source metal 350. Two sides of the first isolation passivation layer 151 respectively extend to an upper end of the gate metal 250 and an upper end of the source metal 350, so that isolation between the gate metal 250 and the source metal 350 is achieved through the first isolation passivation layer 151. A second isolation passivation layer 152 is formed on an upper end and two sides of the field ring metal 450. Two sides of the second isolation passivation layer 152 respectively extend to the upper end of the source metal 350 and an upper end of the drain metal 550, so that isolation between the field ring structure and the gate metal 250, as well as isolation between the field ring structure and the source metal 350, is achieved through the second isolation passivation layer 152.

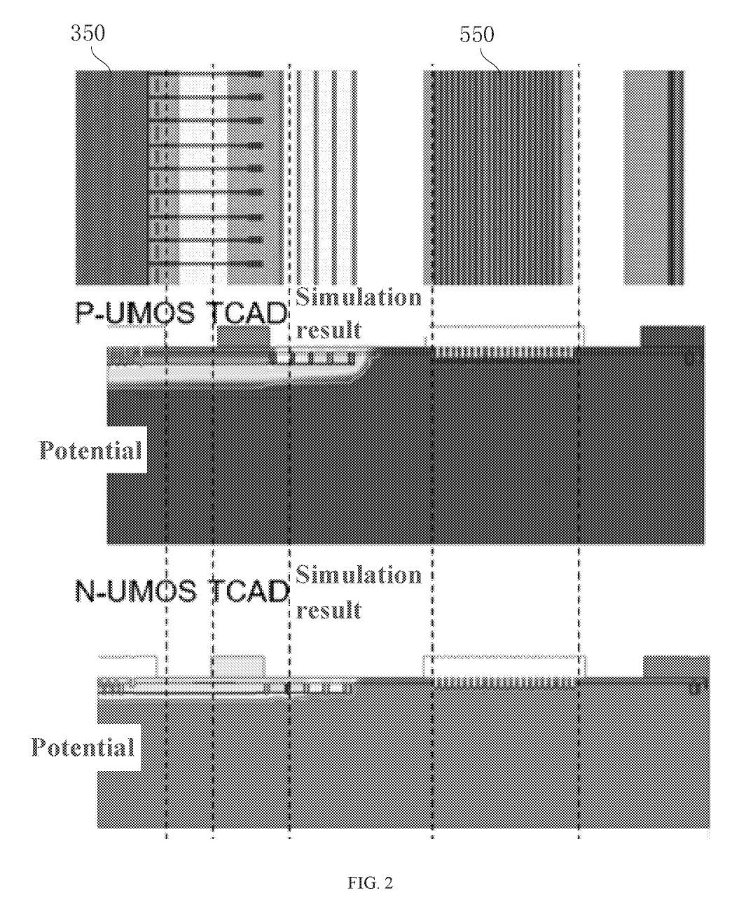

Please refer to FIG. 2, where an upper diagram of FIG. 2 is a metal wiring diagram of the power device, and middle and lower diagrams of FIG. 2 are potential simulation diagrams of a P_UMOS product and an N_UMOS product of the embodiment. As shown in FIG. 2, in any one of the P_UMOS product and the N_UMOS product, due to an isolation effect of the field ring structure, a potential on the front side of the termination peripheral region 500 is basically the same as a potential of the substrate 100 on the rear side thereof. Therefore, disposing the drain metal 550 on the front side of the termination peripheral region 500 of the power device does not affect performance of the power device.

In the present disclosure, from a perspective of product-level cost control and through simulation experiments on the power device, it is found that the potential on a front side of the termination peripheral region 500 of the power device is substantially the same as the potential of the substrate 100 on the rear side of the power device. Accordingly, the drain metal 550 on the rear side of the power device is instead disposed within the termination peripheral region 500 on the front side of the power device, so that the source metal 350, the drain metal 550, and the gate metal 250 of the power device are all located on a single plane (i.e., the front side of the power device), which effectively reduces a requirement for clip materials, enhances performance of the power device, and reduces parasitic effects.

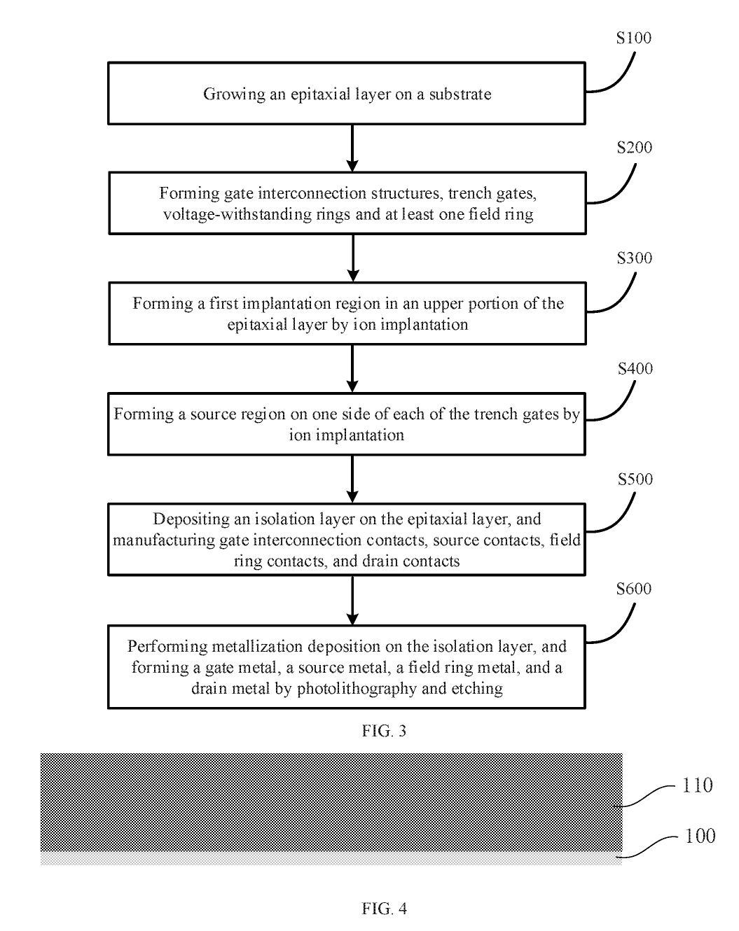

FIG. 3 is a flowchart of a manufacturing method of a power device according to one embodiment of the present disclosure. As shown in FIG. 3, the manufacturing method comprises steps S100-S700.

As shown in FIG. 4, the step S100 comprises growing an epitaxial layer 110 on a substrate 100.

As shown in FIG. 5, the step S200 comprises dividing a gate contact region 200, an active region 300, a termination region 400, and a termination peripheral region 500 along a horizontal direction, forming gate interconnection structures 211 in the gate contact region 200, forming trench gates 311 in the active region 300, and forming voltage-withstanding rings 411 and at least one field ring 421 in the termination region 400. The step S200 comprises steps S210-S230.

The step S210 comprises dividing the gate contact region 200, the active region 300, the termination region 400, and the termination peripheral region 500 along the horizontal direction on the epitaxial layer 110.

The step S220 comprises forming gate interconnection trenches 210 in the gate contact region 200, forming gate trenches 310 in the active region 300, and forming voltage-withstanding ring trenches 410 and at least one field ring trench 420 in the termination region 400.

The step S230 comprises respectively forming the trench gates 311 in the gate trenches 310, respectively forming the gate interconnection structures 211 in the gate interconnection trenches 210, respectively forming the voltage-withstanding rings 411 in the voltage-withstanding ring trenches 410, and forming the at least one field ring 421 in the field ring trench 420. The manufacturing methods for above structures are all conventional processes in the prior art and are unrelated to the improvements of the present disclosure; therefore, they are not described in detail herein.

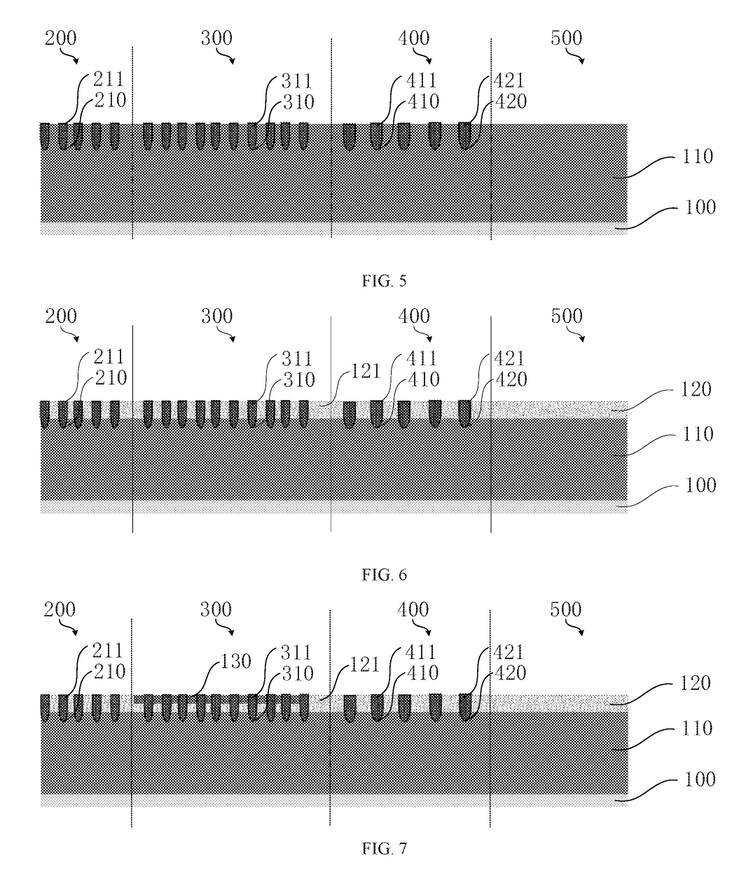

As shown in FIG. 6, the step S300 comprises forming a first implantation region 120 in an upper portion of the epitaxial layer 110 by ion implantation. A thickness of the first implantation region 120 is less than a depth of the at least one field ring 421, and a portion of the first implantation region 120 within the gate contact region 200 and the active region 300 forms a body region 121.

As shown in FIG. 7, step S400 comprises forming a source region 130 on one side of each of the trench gates 311 by ion implantation.

Step S500 comprises depositing an isolation layer 140 on the epitaxial layer 110, and manufacturing gate interconnection contacts 231, source contacts (i.e.,the first source contacts 331 and the second source contact 341), field ring contacts, and drain contacts 531 that extend through the isolation layer 140. The gate interconnection contacts 231 are connected to the gate interconnection structures 211, the source contacts are connected to the source region 130, the field ring contacts are connected to the at least one field ring 421, and the drain contacts 531 are connected to a portion of the first implantation region 120 within the termination peripheral region 500. The step S500 comprises steps S510-S530.

As shown in FIG. 8, the step S510 comprises depositing silicon dioxide on the epitaxial layer 110 to form the isolation layer 140.

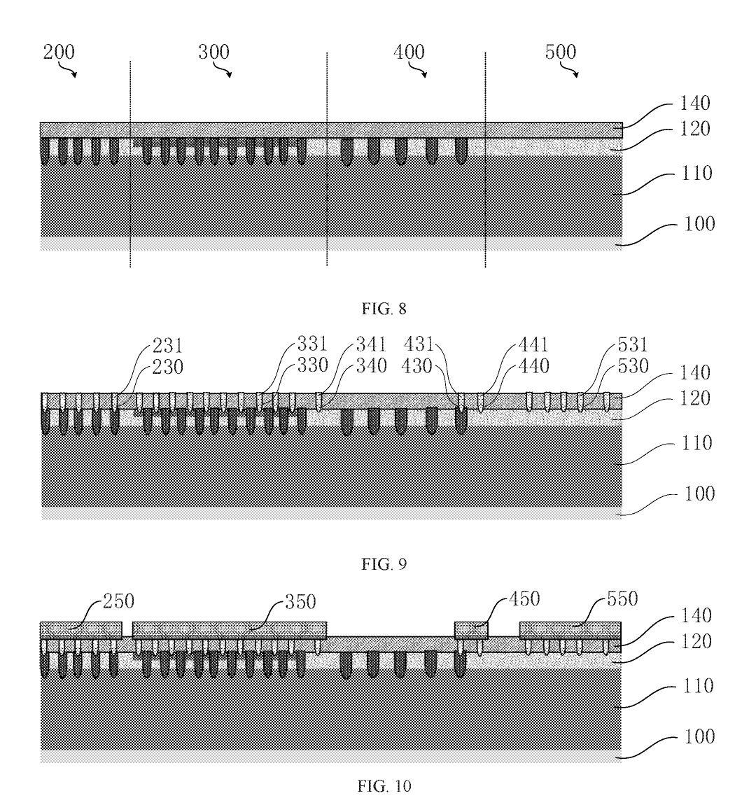

As shown in FIG. 9, the step S520 comprises forming gate interconnection contact holes 230 extending through the isolation layer 140 and into the gate interconnection structures 211 on a portion of the isolation layer 140 within the gate contact region 200; forming first active region contact holes 330 and a second active region contact hole 340 on a portion of the isolation layer 140 within the active region 300; forming a first field ring contact hole 430 and a second field ring contact hole 440 on a portion of the isolation layer 140 within the termination region 400, and forming drain pad contact holes 530 extending through the isolation layer 140 and into the first implantation region 120 on a portion of the isolation layer 140 within the termination peripheral region 500. The first active region contact holes 330 extend through the isolation layer 140 and into the source region 130. The second active region contact hole 340 extends through the isolation layer 140 and into a portion of the body region 121 between the gate trenches 310 and the voltage-withstanding ring trenches 410. The first field ring contact hole 430 extends through the isolation layer 140 and into the at least one field ring 421. The second field ring contact hole 440 extends through the isolation layer 140 and into a portion of the first implantation region 120 on one side of the at least one field ring 421 adjacent to the termination peripheral region 500.

As shown in FIG. 9, the step S530 comprises forming the gate interconnection contacts 231 in the gate interconnection contact holes 230, first source contacts 331 in the first active region contact holes 330, a second source contact 341 in the second active region contact hole 340, a first field ring contact 431 in the first field ring contact hole 430, a second field ring contact 441 in the second field ring contact hole 440, and the drain contacts 531 in the drain pad contact holes 530, by depositing metal.

As shown in FIG. 10, the step S600 comprises performing metallization deposition on the isolation layer 140, and forming a gate metal 250, a source metal 350, a field ring metal 450, and a drain metal 550 that are isolated from each other by photolithography and etching. The gate metal 250 is connected to the gate interconnection contacts 231. The source metal 350 is connected to the source region 130 contacts. The field ring metal 450 is connected to the field ring contacts. The drain metal 550 is connected to the drain contacts 531.

The step S700 comprises depositing silicon dioxide and/or silicon nitride to form a passivation layer, and performing photolithography and etching on the passivation layer to form a first isolation passivation layer 151 and a second isolation passivation layer. The first isolation passivation layer 151 is disposed between the gate metal 250 and the source metal 350. Two sides of the first isolation passivation layer 151 respectively extend to an upper end of the gate metal 250 and an upper end of the source metal 350, so that isolation between the gate metal 250 and the source metal 350 is achieved through the first isolation passivation layer 151. The second isolation passivation layer 152 is formed on an upper end and two sides of the field ring metal 450. Two sides of the second isolation passivation layer 152 respectively extend to the upper end of the source metal 350 and an upper end of the drain metal 550, so that isolation between the field ring structure and the gate metal 250, as well as isolation between the field ring structure and the source metal 350, is achieved through the second isolation passivation layer 152.

In the embodiment, the drain metal 550 of the power device is modified to be disposed in the termination peripheral region 500 on the front side of the power device, so that the source metal 350, the drain metal 550, and the gate metal 250 of the power device are all located on the same plane, which effectively reduces the demand for clip materials, improves the performance of the power device, and reduces parasitic effects.

What is claimed is:

1. A power device, comprising:
a substrate;
an epitaxial layer disposed on the substrate; and
an isolation layer disposed on the epitaxial layer;
wherein the power device is divided into a gate contact region, an active region, a termination region, and a termination peripheral region along a horizontal direction;
wherein a first implantation region is disposed above the epitaxial layer;
wherein a portion of the first implantation region within the gate contact region and the active region form a body region, gate interconnection structures are disposed in a portion of the epitaxial layer within the gate contact region, a gate metal is disposed on a portion of the isolation layer within the gate contact region, and the gate metal is connected to the gate interconnection structures;
wherein trench gates and second implantation regions are disposed in a portion of the epitaxial layer within the active region, each of the second implantation regions is disposed on one side of a corresponding one of the trench gates to form a source region, a source metal is disposed on the isolation layer within the active region, and the source metal is connected to each source region;
wherein voltage-withstanding rings and a field ring structure are disposed in the termination region, a drain metal is disposed on a portion of the isolation layer within the termination peripheral region, and the drain metal is connected to a portion of the first implantation region within the termination peripheral region.

2. The power device according to claim 1, wherein a field ring metal is disposed on a portion of the isolation layer within the termination region, a first isolation passivation layer is formed between the gate metal and the source metal, and a second isolation passivation layer is formed on an upper end and two sides of the field ring metal.

3. The power device according to claim 1, wherein gate interconnection trenches are formed in the gate contact region, a depth of each of the gate interconnection trenches is greater than a depth of the body region, and gate interconnection structures are formed by depositing polysilicon in the gate interconnection trenches;
wherein gate trenches are formed in the active region, a depth of each of the gate trenches is greater than the depth of the body region, and the trench gates are formed by depositing the polysilicon in the gate trenches;
wherein voltage-withstanding ring trenches and at least one field ring trench are formed in the termination region, at least one field ring trench is located on one side of the termination region away from the active region, and depths of the voltage-withstanding ring trenches and the at least one field ring trench are all greater than the depth of the body region;
wherein the voltage-withstanding rings are formed by depositing the polysilicon in the voltage-withstanding ring trenches, and the at least one field ring is formed by depositing the polysilicon in the at least one field ring trench.

4. The power device according to claim 1, wherein gate interconnection contact holes extending through the isolation layer and into the gate interconnection structures are formed on the portion of the isolation layer within the gate contact region, gate interconnection contacts are respectively formed in the gate interconnection contact holes, and the gate metal is connected to the gate interconnection structures through the gate interconnection contacts;
wherein first active region contact holes and a second active region contact hole are formed on a portion of the isolation layer within the active region, the first active region contact holes extend through the isolation layer and into the source region, and the second active region contact hole extends through the isolation layer and into a portion of the body region between the trench gates and the voltage-withstanding rings;
wherein first source contacts are formed in the first active region contact holes, a second source contact is formed in the second active region contact hole, the source metal is connected to the source region through the first source contacts, and the source metal is connected to the portion of the body region between the gate trenches and the voltage-withstanding ring trenches through the second source contact.

5. The power device according to claim 3, wherein a first field ring contact hole and a second field ring contact hole are formed on a portion of the isolation layer within the termination region, the first field ring contact hole extends through the isolation layer and into the at least one field ring, and the second field ring contact hole extends through the isolation layer and into a portion of the first implantation region on one side of the at least one field ring adjacent to the termination peripheral region;
wherein a first field ring contact is formed in the first field ring contact hole, and a second field ring contact is formed in the second field ring contact hole;
wherein a field ring metal is formed on the portion of the isolation layer within the termination region, the field ring metal covers an upper end of the first field ring contact hole and an upper end of the second field ring contact hole, the field ring metal is connected to the at least one field ring through the first field ring contact, and the field ring metal is connected to the first implantation region through the second field ring contact, so as to form the at least one field ring.

6. The power device according to claim 1, wherein drain pad contact holes are formed on the portion of the isolation layer within the termination peripheral region, and the drain pad contact holes extend through the isolation layer and into the first implantation region;
wherein drain contacts are respectively formed in the drain pad contact holes, and the drain metal is connected to a portion of the first implantation region within the termination peripheral region through the drain contacts.

7. A manufacturing method for a power device, comprising steps:
S100: growing an epitaxial layer on a substrate;
S200: dividing a gate contact region, an active region, a termination region, and a termination peripheral region along a horizontal direction, forming gate interconnection structures in the gate contact region, forming trench gates in the active region, and forming voltage-withstanding rings and at least one field ring in the termination region;
S300: forming a first implantation region in an upper portion of the epitaxial layer by ion implantation, wherein a thickness of the first implantation region is less than a depth of the at least one field ring, and a portion of the first implantation region within the gate contact region and the active region form a body region;
S400: forming a source region on one side of each of the trench gates by ion implantation;
S500: depositing an isolation layer on the epitaxial layer, and manufacturing gate interconnection contacts, source contacts, field ring contacts, and drain contacts that extend through the isolation layer; wherein the gate interconnection contacts are respectively connected to the gate interconnection structures, each of the source contacts is connected to a corresponding source region, one of the field ring contacts is connected to the at least one field ring, and the drain contacts are connected to a portion of the first implantation region within the termination peripheral region; and
S600: performing metallization deposition on the isolation layer, and forming a gate metal, a source metal, a field ring metal, and a drain metal that are isolated from each other by photolithography and etching; wherein the gate metal is connected to the gate interconnection contacts, the source metal is connected to the source contacts, the field ring metal is connected to the field ring contacts, and the drain metal is connected to the drain contacts.

8. The manufacturing method according to claim 7, wherein the step S200 comprises steps:
S210: dividing the gate contact region, the active region, the termination region, and the termination peripheral region along the horizontal direction on the epitaxial layer;
S220: forming gate interconnection trenches in the gate contact region, forming gate trenches in the active region, and forming voltage-withstanding ring trenches and at least one field ring trench in the termination region; and
S230: forming the trench gates in the gate trenches, forming the gate interconnection structures in the gate interconnection trenches, forming the voltage-withstanding rings in the voltage-withstanding ring trenches, and forming the at least one field ring in the at least one field ring trench.

9. The manufacturing method according to claim 7, wherein the step S500 comprises steps:
S510: depositing silicon dioxide on the epitaxial layer to form the isolation layer;
S520: forming gate interconnection contact holes extending through the isolation layer and into the gate interconnection structures on a portion of the isolation layer within the gate contact region; forming first active region contact holes and a second active region contact hole on a portion of the isolation layer within the active region ; forming a first field ring contact hole and a second field ring contact hole on a portion of the isolation layer within the termination region; and forming drain pad contact holes extending through the isolation layer and into the first implantation region on a portion of the isolation layer within the termination peripheral region; wherein the first active region contact holes extend through the isolation layer and into the source region, the second active region contact hole extends through the isolation layer and into a portion of the body region between the gate trenches and the voltage-withstanding ring trenches, the first field ring contact hole extends through the isolation layer and into the at least one field ring, and the second field ring contact hole extends through the isolation layer and into a portion of the first implantation region on one side of the at least one field ring adjacent to the termination peripheral region; and
S530: forming the gate interconnection contacts in the gate interconnection contact holes, first source contacts in the first active region contact holes, a second source contact in the second active region contact hole, a first field ring contact in the first field ring contact hole, a second field ring contact in the second field ring contact hole, and the drain contacts in the drain pad contact holes by depositing metal.

10. The manufacturing method according to claim 7, wherein after the step S600, the manufacturing method comprises a step:
S700: depositing silicon dioxide and/or silicon nitride to form a passivation layer, and performing photolithography and etching on the passivation layer to form a first isolation passivation layer and a second isolation passivation layer; wherein the first isolation passivation layer is disposed between the gate metal and the source metal, and the second isolation passivation layer is disposed on an upper end and two sides of the field ring metal.
